(19) United States
(12) Patent Application Publication
(10) Pub. No.: US 2017/0196129 A1
(43) Pub. Date: Jul. 6, 2017

(54) DEVICE FOR PREVENTING DATA THEFT, USE OF FALSE IDENTITY, AND FRAUD DURING CONTACTLESS DATA TRANSMISSION VIA ELECTROMAGNETIC RADIO WAVES

(71) Applicant: Marco Feusi, CH-6934 Bioggio (CH)

(72) Inventor: Marco Feusi, CH-6934 Bioggio (CH)

(21) Appl. No.: 15/303,840

(22) PCT Filed: Apr. 13, 2015
(86) PCT No.: PCT/EP2015/057942

§ 371 Date: Oct. 13, 2016

(30) Foreign Application Priority Data
Apr. 14, 2014 (CH) 00573/14

(51) Int. Cl. H05K 9/00; G06K 19/077; G06F 1/18; G06K 19/073

(52) U.S. Cl. CPC H05K 9/0045; G06K 19/07327; H05K 9/0037; H05K 9/0047; G06K 19/07771; H05K 9/0081; H05K 9/0043; G06F 1/182

(57) ABSTRACT

The application relates to a receptacle comprising a plurality of inside pockets for holding objects, each of which is equipped with an RFID or NFC chip. At least two surfaces of the receptacle which include at least one of the plurality of inside pockets are provided with an electrically conductive layer so that the at least one of the plurality of inside pockets is shielded from electromagnetic radio waves by the at least two surfaces.

### TECHNICAL FIELD

The present invention relates to a device for preventing data theft, use of false identity and payment fraud during contactless data transmission via electromagnetic radio waves. More and more frequently passports, credit, debit and access control cards etc. are being equipped with NFC/RFID radio chips. More precisely, the invention relates to a receptacle with a plurality of inside pockets for holding objects, each of which is equipped with an RFID or NFC chip.

### PRIOR ART

The invention relates to chip cards (health cards/health insurance cards, credit cards/debit cards, travel cards etc.), identity documents (passports, identification cards, employee identification cards, access cards etc.) and next-generation banknotes that are equipped with NFC/RFID radio technology.

In general, GFID transponders are used for this purpose in order to send the data stored on the latter to a receiver by radio transmission and to receive and to store the data transmitted by a transmitter with the RFID chip. At low frequencies this takes place inductively via a near field, and at higher frequencies via an electromagnetic far field. The distance over which an RFID transponder can be read out varies between a few centimeters and more than a kilometer depending on the design (passive/active), the frequency band used, the transmission strength and environmental influences.

Some of the individual types of RFID transponder differ greatly from one another. However, in principle the structure of an RFID transponder consists of an antenna, an analogue circuit for receiving and transmitting (transponder), as well as a digital circuit and a permanent memory chip.

In contrast to active transponders that are operated by a battery, so-called passive RFID transponders obtain their energy for transmission of the information stored on them from the received radio waves of the transmitting and receiving device. These radio waves are called “continuous waves”. With the antenna of the RFID/NFC chip that simultaneously performs the function of an induction coil, a capacitor is charged by induction, which capacitor supplies the RFID/NFC chip, also called a “tag”, with energy. Due to the small capacity of the capacitor, the “continuous wave” must be maintained continuously by the reading device while the “tag” is in the transmitting or receiving mode.

It should additionally be noted that a reading device can only read out a chip card via the front or the rear side, i.e. data cannot be read out via the edges.

DE 20 2010 016 341 U1 specifies a device for preventing undesirable wireless communication. Transportable devices capable of wireless communication are kept in a protective receptacle. In this connection the protective receptacle is made so that it restricts or makes communication impossible between the device and the outside world.

DE 20 2006 002 284 U1 discloses a shielding device for preventing the read-out of passports, identity documents, chip cards and other carrier media which are equipped with RFID radio technology. The read-out of identity papers etc. equipped with RFID is prevented here by means of a shielding cover.

DE 20 2013 003 410 U1 discloses a mobile telephone cover with RFID/NFC protection.

It is common to all of the aforementioned documents that protection is achieved by a full cover.

### SUMMARY OF THE INVENTION

The inventor has recognized that it is disadvantageous to entirely cover the object carrying the RFID/NFC transponder. In particular, the full cover means that a user must make a relatively large amount effort in order to make the object ready for use. With a credit card, for example, the cover with the card located within it must first of all be removed from a purse and then the card still has to be removed from the cover. This additional effort means that, as a result, the known covers are not used, and the transponders are often conveyed without protection. In addition, with a plurality of chip cards etc., the volume of one's purse increases greatly.

Against this background it is the object of the present invention to provide a simple and inexpensive device for preventing data theft, use of false identity and fraud during contactless data transmission via electromagnetic radio waves which overcomes the disadvantages of the prior art described above. In particular, the object is to provide a device that can be used more flexibly, that is easier for a user to use, and so is more reliable. In particular, the object is also to provide a device that is independent of a specific design of NFC/RFID radio chip carrier, e.g. the credit card.

This object is achieved by the device according to claim 1 and the use according to claim 12. Advantageous embodiments of the device emerge from the sub-claims.

Unauthorized access to data of an NFC/RFID radio chip is prevented by an electrically conductive thin pad that can be, for example, a metal element or an object comprising metal or carbon, in particular graphite, preferably two-dimensional, also discontinuously two-dimensional in the form of strips or patterns. A two-dimensional, electrically conductive object is understood to be an object the extension of which over a surface, that can also be bent or kinked, is larger than its extension in a direction perpendicular to the surface by at least one order of magnitude. Likewise, an electrically conductive colored layer prevents read-out. In order to increase its stability, the pad can be composed of plastic, thicker paper, cardboard etc. An electrically conductive layer in between, or on at least one of the sides, is important. The conductive layer can also be made in strips. Particularly effective protection against electromagnetic radio waves is achieved by a graphite coating.

In order to protect a gentleman's wallet, for example, a protective strip can be cut to the size of the innermost compartment and be pushed in here. When the wallet is folded shut, the front and the rear side are automatically protected against unauthorized access.

One can proceed similarly e.g. with a passport. The pad, which can be made to be slightly adhesive, is placed on and fastened to the insides of the passport “cover”. If the passport is folded shut, the inside is protected against unauthorized spying.

Further advantages and features of the invention emerge from the following description of the figures and the claims in their entirety.

### BRIEF DESCRIPTION OF THE FIGURES

FIG. 1 shows a wallet without protection against electromagnetic radio waves.

FIG. 2 shows the wallet from FIG. 1 with a preferred embodiment of the radio wave protection which, for the purposes of illustration, is pushed ⅔ of the way into the wallet.

### WAYS OF IMPLEMENTING THE INVENTION

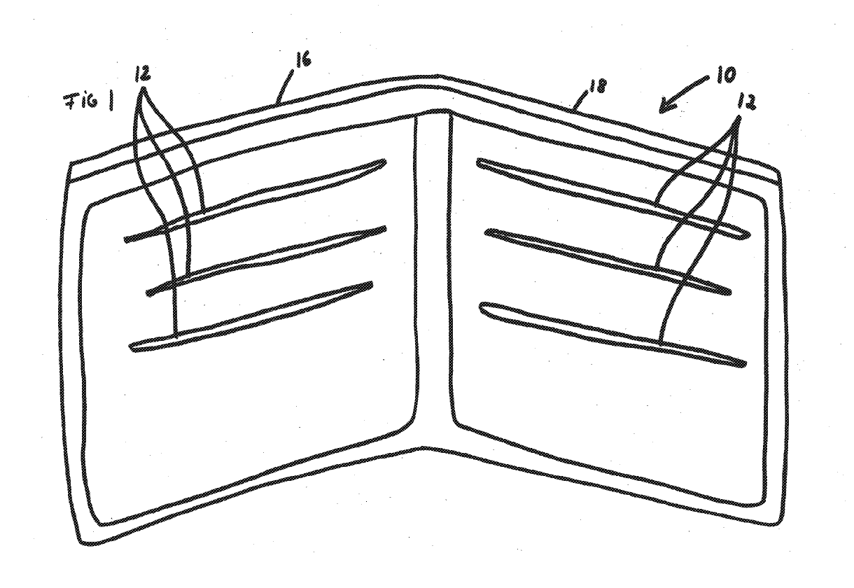

FIG. 1 shows a conventional wallet 10 with six inside pockets 12 for objects, for example credit cards, Maestro cards, money cards, access cards for buildings or car parks, driver's license, identification card or similar cards that can be equipped with an RFID or NFC chip. In the open state of the wallet 10, that is shown in FIG. 1, the inside pockets 12 are directly accessible to a user. Behind the inside pockets 12, i.e. in the closed state inclosing the inside pockets from the outside, two surfaces 16, 18 are defined.

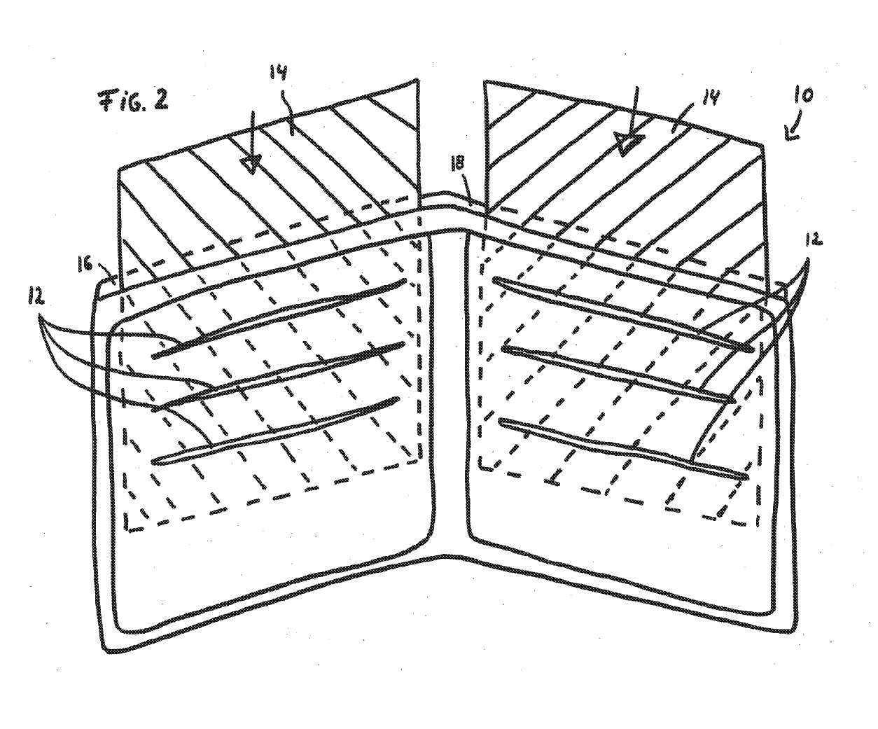

FIG. 2 shows the wallet 10 from FIG. 1 in a preferred embodiment of the present invention. According to the latter an electrically conductive layer in the form of two protective elements 14, which are examples of electrically conductive, two-dimensional objects, are each arranged on the two surfaces 16, 18 so that the inside pockets 12 and the cards located within them are shielded from the outside from electromagnetic radio waves by the surfaces 16, 18 when the wallet is closed. Instead of the protective elements 14 shown in FIG. 2, other at least partially electrically conductive objects can also be used that can preferably be made to be elastic. One example that works well is graphite.

The protective elements 14 preferably have a film onto which, depending on the application, one or more layers of different materials, each with different conductivity, permeability and permittivity, can be vapor deposited. The layer thickness and the sequence of materials changes the electromagnetic properties of the end product. The resulting effect is that specific frequency bands can be specifically dampened. It is thus possible, for example, to effectively shield electromagnetic radiation in the megahertz range, while those in the kilohertz range can penetrate through the protective elements 14. Thus, the reading out of NFC elements, that are generally read out at a frequency of 13.56 MHz, can be prevented, while RFID tags, the working frequency of which is in the kilohertz range, continue to function.

In a particularly preferred embodiment a 35 nm to 50 nm, preferably 40 nm thick aluminum layer is vapor-deposited onto a film, a polyester layer of largely any thickness is applied to the latter, then another 35 nm to 50 nm, preferably 40 nm thick aluminum layer is vapor deposited, another polyester layer of largely any thickness is applied to the latter, and another 35 nm to 50 nm, preferably 40 nm thick aluminum layer is vapor-deposited onto the latter. The protective element 14 thus preferably has three aluminum layers, each with a thickness of 35 nm to 50 nm, preferably 40 nm, that are separated from one another in each instance by a polyester layer. An additional layer, for example a polyester layer, is applied to the outermost aluminum layer or to the outermost aluminum layers in order to protect the aluminum. Furthermore, it is possible to additionally provide a graphite layer on which in particular an RFID antenna or an entire RFID chip can be disposed which is electrically separated from the aluminum layers by the graphite due to its anisotropy. Within this context the anisotropy of the graphite means that a graphite layer electrically conducts along the individual layers of the graphite, whereas it insulates electrically perpendicular to its individual layers. This graphite layer is preferably at least 150 μm thick.

In total, this preferably produces an accumulated layer thickness of aluminum or of some other conductive material of between 70 nm and 200 nm, particularly preferably of between 100 nm and 15 nm.

In an alternative preferred embodiment an aluminum layer that is between 35 nm and 100 nm, preferably 50 nm thick, is respectively applied to both sides of a polyester layer.

The protective element 14 should preferably have an overall thickness of between 80 μm and 150 μm so that it is easy to handle.

In FIG. 2 the protective elements 14 are shown pushed two thirds of the way into the wallet 10 in order to make the protective elements 14 more visible. Provision is made for the finished embodiment such that the protective elements 14 are pushed fully into the wallet 10 so that protection of all of the cards located within the inside pockets 12 is guaranteed.

Unlike the exemplary embodiment shown in FIG. 2, it is for example also possible for a protective element 14 to be made on one piece. Alternatively or additionally, it is also conceivable for protective elements to be applied to the wallet from the outside, for example adhered, stitched, vapor-deposited or fastened in some other way. Alternatively, electrically conductive dyes or materials can be vapor-deposited or printed.

In a preferred embodiment the protective element 14 comprises a plastic base layer, on top of this aluminum or copper film, and on top of this a graphite layer, the sequence of these layers also being able to be varied.

As an alternative to the wallet that is illustrated, the receptacle can be of any other form.

1. A receptacle (10) comprising a plurality of inside pockets (12) for holding objects, each of which objects being equipped with an RFID or NFC chip, wherein the receptacle (10) is provided on at least two surfaces (16, 18), which surround at least one of the plurality of inside pockets (12), with an electrically conductive layer (14) so that the at least one of the plurality of inside pockets (12) is shielded from electromagnetic radio waves by the at least two surfaces (16, 18).

2. The receptacle (10) according to claim 1, wherein the at least two surfaces (16, 18) surround a plurality, preferably all, of the inside pockets (12) of the receptacle (10).

3. The receptacle (10) according to any of the preceding claims, wherein a plurality, preferably all, of the respective conductive layers (14) of the at least two surfaces (16, 18) is formed integrally with one another.

4. The receptacle (10) according to any of the preceding claims, wherein the receptacle (10) is a wallet, a purse, a prepaid card pocket or a passport pocket for holding a plurality of objects equipped with an RFID or NFC chip.

5. The receptacle (10) according to any of the preceding claims, wherein the electrically conductive layer is carbon, in particular graphite, and/or aluminum.

6. The receptacle (10) according to any of the preceding claims, wherein the electrically conductive layer (14) is a multi-layered structure that comprises at least aluminum and graphite.

7. The receptacle (10) according to any of the preceding claims, the electrically conductive layer (14) having an overall thickness of between 80 nm and 150 nm.

8. The receptacle (10) according to any of the preceding claims, wherein the electrically conductive layer (14) has an accumulated thickness of aluminum of between 70 nm and 200 nm, preferably of between 100 nm and 150 nm.

9. The receptacle (10) according to any of the preceding claims, wherein the electrically conductive layer (14) is a multi-layered structure that comprises a plurality of layers, preferably three layers, with aluminum and a polyester layer in between in each case,
wherein preferably a polyester layer is further being disposed on an outer side of one of the layers of aluminum,
wherein preferably a graphite layer is further disposed on an outer side of one of the layers of aluminum.

10. The receptacle (10) according to any of the preceding claims, wherein the electrically conductive layer (14) comprises graphite, and one or a plurality of antennae of one or a plurality of RFID chips being disposed on the graphite.

11. The receptacle (10) according to any of the preceding claims, wherein the electrically conductive layer (14) comprises two elements of a size differing from the size of a credit card by a maximum of 10%, which elements are disposed on opposing sides of a compartment for credit cards within the receptacle (10).

12. Use of an electrically conductive, two-dimensional object (14) for simultaneously shielding a plurality of objects that are held in a receptacle (10) with a plurality of inside pockets (12), each of which is equipped with an RFID or NFC chip, from electromagnetic radio waves from outside of the receptacle (10).

13. The use of an electrically conductive, two-dimensional object (14) according to claim 12, the electrically conductive, two-dimensional object (14) being made to be self-adhesive.

14. The use of an electrically conductive, two-dimensional object (14) according to claim 12 or 13, the electrically conductive, two-dimensional object (14) being applied, in particular vapor-deposited or adhered, to a substrate, the substrate being a plastic, paper, cardboard or the like.

15. The use of an electrically conductive, two-dimensional object (14) according to any of claims 12 to 14, the electrically conductive, two-dimensional object (14) being introduced between two two-dimensional substrates.

16. The use of an electrically conductive, two-dimensional object (14) according to any of claims 12 to 15, the electrically conductive, two-dimensional object (14) being able to be cut to shape and/or folded into the shape and size of the receptacle (10) by a user.

17. The use of an electrically conductive, two-dimensional object according to any of claims 12 to 16, the electrically conductive layer being carbon, in particular graphite, and/or aluminum and/or copper.

18. The use of an electrically conductive, two-dimensional object (14) according to any of claims 12 to 17 for a receptacle (10) according to any of claims 1 to 11.
